(19) United States
(12) Patent Application Publication
(10) Pub. No.: US 2009/0108448 A1
(43) Pub. Date: Apr. 30, 2009

(54) METAL PAD OF SEMICONDUCTOR DEVICE

(76) Inventor: Jong-Bok Lee, Bucheon-si (KR)

Correspondence Address: SHERR & VAUGHN, PLLC, 620 HERNDON PARKWAY, SUITE 200, HERNDON, VA, 20170, US

(21) Appl. No.: 12/247,521

(22) Filed: Oct. 8, 2008

(30) Foreign Application Priority Data
Oct. 25, 2007 (KR) 10-2007-00107736

(51) Int. Cl. H01L 23/488; H01L 21/44

(52) U.S. Cl. 257/738; 438/614; 257/773; 257/E21.476; 257/E23.023

(57) ABSTRACT

A metal pad of a semiconductor device that prevents cracking during a ball bonding process in a metal pad applied to a wafer level package (WLP). The metal pad includes a main metal pad formed on and/or over a semiconductor substrate and electrically connected to a contact plug, and a dummy metal pad electrically isolated from the main metal pad and formed at a peripheral portion of the main metal pad to surround the main metal pad.

The present application claims priority under 35 U.S.C. §119 to Korean Patent Application No. 10-2007-0107736 (filed on Oct. 25, 2007), which is hereby incorporated by reference in its entirety.

### BACKGROUND

In general, a semiconductor package fabricated by a wire boding method is larger in size than a semiconductor chip because electrode terminals of a printed circuit board (PCB) are electrically connected to pads of the semiconductor chip by conductive wires. Further, since a wire bonding process requires a long time, there is a limitation in mass production of subminiature semiconductor packages. Particularly, due to the demand for high integration, high performance and high speed of the semiconductor chip, there have been various attempts for miniaturization and mass production of the semiconductor packages. For example, a semiconductor package may have pads of a semiconductor chip electrically connected to electrode terminals of a PCB directly through solder or metal bumps formed on and/or over the pads of the semiconductor chip. The semiconductor package using the metal bumps may typically employ a chip-on-glass (COG) method or a tape carrier package (TCP) method. The semiconductor package using the solder bumps typically employs a flip chip ball grid array method or a water level chip/scale package method.

In a chip-on-glass (COG) method, metal bumps are formed on and/or over the pads of the semiconductor chip, and the electrode pads of the semiconductor chip are electrically connected to the electrode terminals of the PCB through the metal bumps by a thermo-compressing and hardening process using a polymer containing anisotropic conductive particles, thereby fabricating a semiconductor package. In the flip chip ball grid array method, the solder bumps in contact with the pads of the semiconductor chip are electrically connected to the pads of the substrate, and an under filling process is performed to protect the solder bumps from external environment or a physical impact. Further, the balls are attached to the rear surface of the substrate in contact with the semiconductor chip to be electrically connected to the electrode terminals of the PCB, thereby fabricating a semiconductor package. In the water level chip/scale package method, the chip and the package may be formed in the same size through rearrangement and the metal bumps for light, thin, short, and small products.

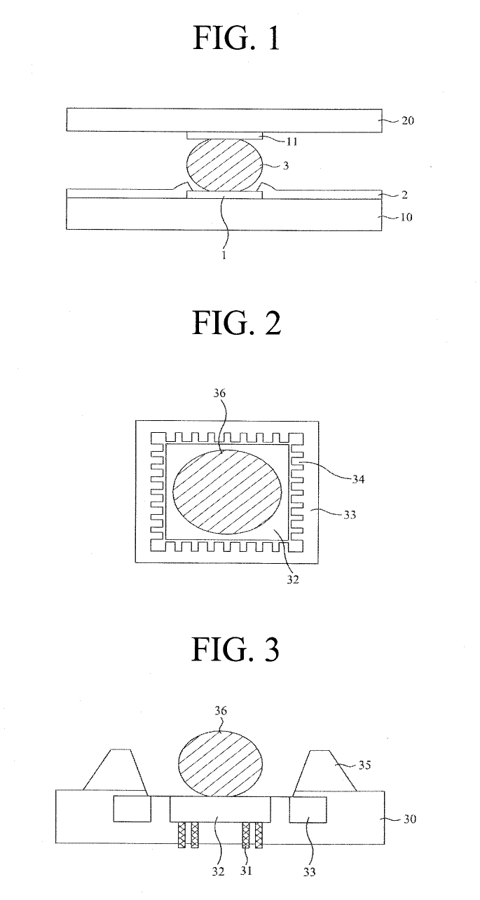

As illustrated in example FIG. 1, a method for fabricating a semiconductor package using solder bumps may include semiconductor chip 10 having metal pad 1 formed thereon and/or thereover, passivation film 2 formed on and/or over the surface of semiconductor chip 10 having metal pad 1 to selectively expose metal pad 1, metal ball 3 formed on and/or over metal pad 1, and printed circuit board 20 having an electrode terminal 11 in contact with the upper surface of metal ball 3. Metal ball 3 is formed on and/or over metal pad 1 of semiconductor chip 10, and printed circuit board 20 having electrode terminal 11 is prepared. After metal ball 3 of semiconductor chip 10 and electrode terminal 11 of printed circuit board 20 are arranged, heat and pressure are applied to semiconductor chip 10 and printed circuit board 20 such that metal pad 1 of semiconductor chip 10 is electrically connected to electrode terminal 11 of printed circuit board 20 through metal ball 3.

However, such a semiconductor package and method has a variety of disadvantages. For instance, after metal ball 3 and electrode terminal 11 of printed circuit board 20 are arranged, when heat and pressure are applied to semiconductor chip 10 and printed circuit board 20 such that metal pad 1 of semiconductor chip 10 is electrically connected to electrode terminal 11 of printed circuit board 20 through metal ball 3, cracking occurs in metal pad 1 of semiconductor chip 10 by thermal stress, mechanical pressure and abnormal pressure. Accordingly, a defect is generated in passivation film 2 and semiconductor chip 10, thereby causing malfunction of semiconductor chip 10.

### SUMMARY

Embodiments relate to a semiconductor device, and more particularly to a metal pad of a semiconductor device that prevents generation of cracks in a ball bonding process in a metal pad applied to a wafer level package (WLP).

Embodiments relate to a metal pad of a semiconductor device that prevents cracks from being generated in the metal pad of the semiconductor chip due to thermal stress and abnormal pressure.

Embodiments relate to a metal pad of a semiconductor device that prevents cracks from propagating into a semiconductor chip, thereby preventing defects of the semiconductor chip.

Embodiments relate to a semiconductor device that may include at least one of the following: a main metal pad formed on and/or over a semiconductor substrate; a contact plug electrically connected to the main metal pad; and a dummy metal pad formed spaced and electrically isolated from the main metal pad.

Embodiments relate to a method of forming a semiconductor device that may include at least one of the following steps: forming a lower line over a semiconductor substrate; and then forming an insulating film over the semiconductor substrate including the lower line; and then forming a contact plug in the interlayer insulating film and electrically connected to the lower line; and then simultaneously forming a main metal pad and a dummy metal pad over the insulating film such that the main metal pad is electrically connected to the contact plug and the dummy metal pad is formed spaced apart a predetermined distance and electrically isolated from the main metal pad.

Embodiments relate to an apparatus that may include at least one of the following: a semiconductor substrate; a metal line formed over the semiconductor substrate; an insulating film formed over the semiconductor substrate including the metal line; contact plugs formed extending through the insulating film and electrically connected to the metal line; a first metal pad portion formed over the insulating film and electrically connected to the contact plugs; a second metal pad portion formed over the insulating film and electrically isolated and spaced apart from the first metal pad portion, the second metal pad portion including a plurality or protrusions extending from an inner periphery thereof; and a passivation film formed over the second metal pad portion such that the uppermost surface of the first metal pad portion is exposed.

The metal pad of the semiconductor device in accordance with embodiments has the following effects. The dummy metal pad is formed spaced laterally from the main metal pad of the semiconductor chip electrically connected to the electrode terminal of the printed circuit board to cover the main metal pad, and a plurality of protrusions and/or depressions formed extending from the dummy metal pad. Thus, when the main metal pad of the semiconductor chip is electrically connected to the electrode terminal of the printed circuit board through the metal ball, it is possible to prevent one or more cracks from being generated in the metal pad of the semiconductor chip due to thermal stress and abnormal pressure and prevent the crack from propagating into the semiconductor chip, thereby preventing defects of the semiconductor chip.

### DRAWINGS

Example FIG. 1 illustrates a semiconductor package.

Example FIGS. 2 to 4 illustrate a metal pad of a semiconductor device and a method for forming a pad of a semiconductor chip in accordance with embodiments.

### DESCRIPTION

Reference will now be made in detail to embodiments, examples of which are illustrated in the accompanying drawings. Wherever possible, the same reference numbers will be used throughout the drawings to refer to the same or like parts.

As illustrated in example FIGS. 2 and 3, semiconductor device 30 includes a photodiode, a thin film transistor, a capacitor and the like formed on and/or over a semiconductor substrate, and an interlayer insulating film formed on and/or over the entire surface thereof. A contact hole is formed in the interlayer insulating film to connect the semiconductor device with an external circuit. A metal layer is filled in the contact hole to form contact plug 31. Main metal pad 32 connected to contact plug 31 is formed on and/or over the interlayer insulating film. Dummy metal pad 33 is formed on and/or over the interlayer insulating film laterally spaced from main metal pad 32. Main metal pad 32 and dummy metal pad 33 is electrically isolated from each other. Dummy metal pad 33 has a plurality of protrusions and depressions 34 extending from an inner peripheral surface thereof. Protrusions and depressions 34 may be formed in the space between dummy metal pad 33 and main metal pad 32. Main metal pad 32 is spaced from dummy metal pad 33 by a predetermined distance, such as in a range between approximately 1 μm to 10 μm. A series of protrusions and depressions 34 are formed to be protruded from dummy metal pad 33 by a predetermined distance, such as in a range between approximately 1 μm to 5 μm.

Main metal pad 32 and dummy metal pad 33 may be formed in a rectangular geometric shape. A corner portion of dummy metal pad 33 is formed to have the same height and width, ranging between approximately 1 μm×1 μm to 10 μm×10 μm with regard to the design according to the chip size, to be rounded in a wafer process. The size of dummy metal pad 33 and main metal pad 32 corresponds to the size of a metal pad. Meaning, a peripheral portion of dummy metal pad 33 corresponds to a peripheral portion of a metal pad. Passivation film 35 is formed on and/or over the surface of semiconductor device 30 including main metal pad 32 and dummy metal pad 33 to selectively expose main metal pad 32. Metal ball 36 is formed on and/or over main metal pad 32. Further, a printed circuit board having an electrode terminal is prepared at a portion corresponding to metal ball 36. After metal ball 36 of semiconductor device 30 and the electrode terminal of the printed circuit board are arranged, heat and pressure are applied to semiconductor device 30 and printed circuit board such that main metal pad 32 of semiconductor device 30 is electrically connected to the electrode terminal of the printed circuit board through metal ball 36.

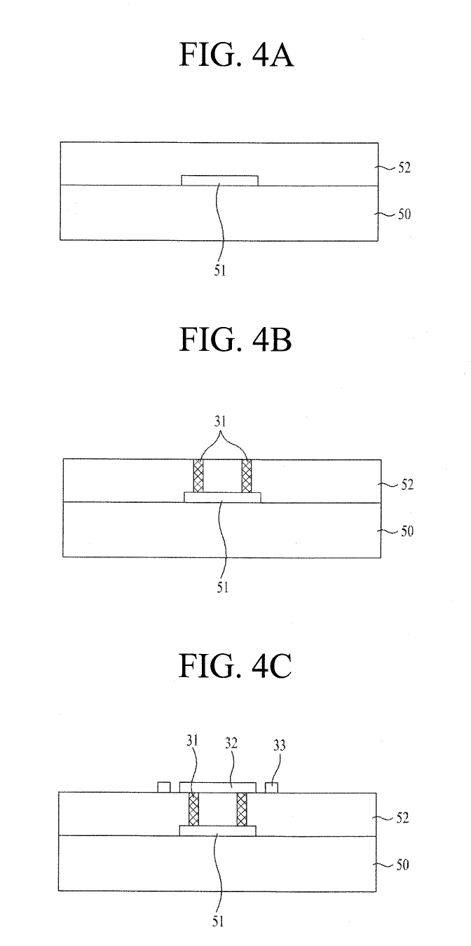

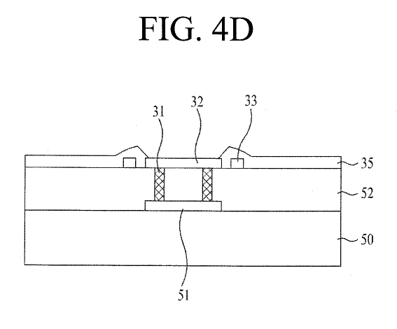

As illustrated in example FIG. 4A, a method for forming a pad of a semiconductor chip in accordance with embodiments may include a semiconductor device such as at least one of a photodiode, a thin film transistor or a capacitor, and lower line 51 formed on and/or over semiconductor substrate 50 including the semiconductor devices. Interlayer insulating film 52 is formed on and/or over the entire surface of substrate 50 including lower line 51.

As illustrated in example FIG. 4B, interlayer insulating film 52 is selectively removed to expose portions of metal line 51, thereby forming contact holes. A conductive material is then deposited to be filled in the contact holes and a chemical mechanical polishing (CMP) process is performed to thereby form contact plugs 31 in respective contact holes and electrically connected to metal line 51.

As illustrated in example FIG. 4C, a metal layer is deposited on and/or over interlayer insulating film 52 including contact plugs 31 and is selectively removed to simultaneously form main metal pad 32 and dummy metal pad 33. Main metal pad 32 is formed on and/or over and electrically connected to contact plugs 31. Main metal pad 32 and dummy metal pad 33 may be formed of at least one of titanium, titanium alloy, aluminum, aluminum alloy, nickel, nickel alloy, copper, copper alloy, chromium, chromium alloy, gold, gold alloy or the like. Main metal pad 32 and dummy metal pad 33 may have the same structural configurations as those illustrated in example FIGS. 2 and 3. Meaning, dummy metal pad 33 is formed on lateral sides of main metal pad 32. Main metal pad 32 and dummy metal pad 33 are electrically isolated from each other by a passivation film 35 to be described later. Further, dummy metal pad 33 has a plurality of protrusions and depressions 34 in a space between dummy metal pad 33 and main metal pad 32. Main metal pad 32 is spaced from dummy metal pad 33 by a predetermined distance in a range between approximately 1 μn to 10 μm. The protrusions and depressions 34 are formed to be protruded from dummy metal pad 33 by a predetermined distance in a range between approximately 1 μm to 5 μm. The corner portion of dummy metal pad 33 is formed to have the same height and width, ranging from between approximately 1 μm×1 μm to 10 μm×10 μm with regard to the design according to the chip size, to be rounded in a wafer process.

As illustrated in example FIG. 4D, passivation film 35 is deposited on and/or over the entire surface of substrate 51 including main metal pad 32 and dummy metal pad 33. Passivation film 35 is then selectively removed to expose only main metal pad 32 to thereby form a semiconductor chip. As illustrated in example FIG. 3, metal ball 36 is formed on and/or over main metal pad 32. A printed circuit board having an electrode terminal is prepared at a portion corresponding to metal ball 36. After the metal ball of the semiconductor device and the electrode terminal of the printed circuit board are arranged, heat and pressure are applied to the semiconductor device and the printed circuit board, thereby electrically connecting the main metal pad of the semiconductor chip and the electrode terminal of the printed circuit board.

When the main metal pad of the semiconductor chip are electrically connected to the electrode terminal of the printed circuit board through the metal ball, the protrusions and depressions are formed to efficiently prevent a crack from being generated in the metal pad of the semiconductor chip due to thermal stress and abnormal pressure and to efficiently prevent the crack from propagating into the semiconductor chip. The protrusions and depressions may be formed in various shapes such as a circular shape and a triangular shape without being limited to the rectangular shape illustrated in the example drawing figures. Accordingly, cracks propagating force is dispersed due to the prominences and depressions to efficiently prevent the crack from being generated. Further, although the wafer level package is described in accordance with embodiments, embodiments are not limited thereto and may be applied to other package chips.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a semiconductor substrate;
an insulating film formed over the semiconductor substrate;
a contact plug formed in the insulating film;
a main metal pad formed over the insulating film and electrically connected to the contact plug; and
a dummy metal pad formed spaced apart a predetermined distance and electrically isolated from the main metal pad.

2. The semiconductor device of claim 1, wherein the dummy metal pad has a plurality of protrusions and depressions extending from an inner periphery thereof.

3. The semiconductor device of claim 2, wherein the protrusions extend from the dummy metal pad a distance in a range between approximately 1 μm to 5 μm.

4. The semiconductor device of claim 1, wherein the predetermined space is in a range between approximately 1 μm to 10 μm.

5. The semiconductor device of claim 1, wherein the main metal pad and the dummy metal pad are formed having a rectangular cross section.

6. The semiconductor device of claim 5, wherein corner portions of the dummy metal pad each have a height that is equal to a width of the corner portions.

7. The semiconductor device of claim 6, wherein the corner portions of the dummy metal pad each have a size in a range between approximately 1 μm×1 μm to 10 μm×10 μm.

8. The semiconductor device of claim 1, further comprising:
a passivation film formed over the insulating film including portions of the main metal pad and the entire dummy metal pad such that another portion of the main metal pad is exposed;
a metal ball formed over the exposed portion of the main metal pad.

9. The semiconductor device of claim 8, wherein the main metal pad and the dummy metal pad are electrically isolated from each other by the passivation film.

10. The semiconductor device of claim 1, wherein the main metal pad and the dummy metal pad are formed of at least one of titanium, titanium alloys, aluminum, aluminum alloys, nickel, nickel alloys, copper, copper alloys, chromium, chromium alloys, gold and gold alloys.

11. A method for fabricating a semiconductor device comprising:
forming a lower line over a semiconductor substrate; and then
forming an insulating film over the semiconductor substrate including the lower line; and then
forming a contact plug in the interlayer insulating film and electrically connected to the lower line; and then
simultaneously forming a main metal pad and a dummy metal pad over the insulating film,
wherein the main metal pad is electrically connected to the contact plug and the dummy metal pad is formed spaced apart a predetermined distance and electrically isolated from the main metal pad.

12. The method of claim 11, wherein the dummy metal pad has a plurality of protrusions and depressions formed on an inner periphery thereof.

13. The method of claim 12, wherein the protrusions extend from the dummy metal pad a distance in a range between approximately 1 μm to 5 μm.

14. The method of claim 11, wherein the predetermined space is in a range between approximately 1 μm to 10 μm.

15. The method of claim 11, wherein the main metal pad and the dummy metal pad are formed having a rectangular cross section.

16. The method of claim 15, wherein corner portions of the dummy metal pad each have a size in a range between approximately 1 μm×1 μm to 10 μm×10 μm.

17. The method of claim 11, further comprising:
forming a passivation film over the insulating film including the main metal pad and the dummy metal pad; and then
selectively removing a portion of the passivation film to expose a portion of the main metal pad; and then
forming a metal ball over the exposed portion of the main metal pad; and then
electrically connecting the main metal pad to an electrode terminal of a printed circuit board to the semiconductor device and the printed circuit board.

18. The method of claim 17, wherein the passivation film is formed to electrically isolate the main metal pad from the dummy metal pad.

19. The method of claim 11, wherein the main metal pad and the dummy metal pad are composed of one of titanium, titanium alloys, aluminum, aluminum alloys, nickel, nickel alloys, copper, copper alloys, chromium, chromium alloys, gold and gold alloys.

20. An apparatus comprising:
a semiconductor substrate;
a metal line formed over the semiconductor substrate;
an insulating film formed over the semiconductor substrate including the metal line;
contact plugs formed extending through the insulating film and electrically connected to the metal line;
a first metal pad portion formed over the insulating film and electrically connected to the contact plugs;
a second metal pad portion formed over the insulating film and electrically isolated and spaced apart from the first metal pad portion, the second metal pad portion including a plurality or protrusions extending from an inner periphery thereof; and
a passivation film formed over the second metal pad portion such that the uppermost surface of the first metal pad portion is exposed.
